(19) United States
(12) Patent Application Publication
(10) Pub. No.: US 2016/0020729 A1
(43) Pub. Date: Jan. 21, 2016

(54) METHOD, DEVICE, AND SYSTEM FOR DETECTING DIRECT-CURRENT ARC FAULT OF PHOTOVOLTAIC SYSTEM

(71) Applicant: Sungrow Power Supply Co., Ltd., Hefei (CN)

(72) Inventors: Yanfei YU, Hefei (CN); Hua NI, Hefei (CN); Wei ZHAO, Hefei (CN); Yanfeng ZHOU, Hefei (CN)

(73) Assignee: Sungrow Power Supply Co., Ltd., Hefei (CN)

(21) Appl. No.: 14/802,291

(22) Filed: Jul. 17, 2015

(30) Foreign Application Priority Data
Jul. 21, 2014 (CN) 201410348482.X

(51) Int. Cl. G01R 31/40; G01R 31/02; G01R 29/26

(52) U.S. Cl. CPC H02S 50/00; G01R 29/26; G01R 31/025

(57) ABSTRACT

A method for detecting a direct-current arc fault of a photovoltaic system is provided. The method includes: obtaining operation parameters of a photovoltaic system, and a current noise signal in a direct-current cable of the photovoltaic system, respectively; adjusting, based on the operation parameters, a threshold, where the threshold is used to determine whether the current noise signal has an arc feature; and sending a photovoltaic system direct-current arc fault signal in a case that it is determined, based on the threshold, that the current noise signal has a arc feature, so as to improve precision in the direct-current arc fault detection of the photovoltaic system. A device, a processor, and a system for detecting a direct-current arc fault of a photovoltaic system are also provided.

This application claims priority to Chinese Patent Application No. 201410348482.X, titled “METHOD, DEVICE, PROCESSOR, AND SYSTEM FOR DETECTING DIRECT-CURRENT ARC FAULT OF PHOTOVOLTAIC SYSTEM”, filed with the Chinese State Intellectual Property Office on Jul. 21, 2014, which is incorporated by reference in its entirety herein.

### FIELD

The present disclosure relates to the field of photovoltaic electric power generation technology, and particularly to a method, a device, and a system for detecting a direct-current arc fault of a photovoltaic system.

### BACKGROUND

A direct-current arc fault of a photovoltaic system is a direct-current arc discharge phenomenon caused by poor contact of conductors at a direct-current side in the photovoltaic system. Since a direct-current arc is free gas with a high temperature and high electrical conductivity, it is extremely easy to cause an electric shock hazard to people, damages to a device, and a fire accident. Therefore, direct-current arc fault detection is very important to the photovoltaic system.

A current noise in a direct-current cable of the photovoltaic system is increased by the current-direct arc fault, so in a conventional method for detecting a direct-current arc fault, it is determined based on amplitude of the current noise whether a direct-current arc fault occurs. However, a disadvantage of the conventional method is that a fixed threshold is adopted to determine the amplitude of the current noise, which can not adapt to a varied operation environment of the photovoltaic system, and is apt to lead to a misjudgment.

Hence, a resolution for improving precision of the direct-current arc fault detection in the photovoltaic system is highly required.

### SUMMARY

In view of this, a method, a device, and a system for detecting a direct-current arc fault of a photovoltaic system are provided in the present disclosure, to improve precision in direct-current arc fault detection for the photovoltaic system.

A method for detecting a direct-current arc fault of a photovoltaic system is provided, and the method includes:

obtaining operation parameters of a photovoltaic system and a current noise signal in a direct-current cable of the photovoltaic system, respectively;

adjusting, based on the operation parameters, a threshold, where the threshold is used to determine whether the current noise signal has an arc feature; and

sending a photovoltaic system direct-current arc fault signal in a case that it is determined based on the threshold that the current noise signal has the arc feature.

Specifically, the operation parameters include an operation temperature signal of the photovoltaic system and/or a direct current signal in the direct-current cable of the photovoltaic system.

Specifically, the determining, based on the threshold, whether the current noise signal has an arc feature includes: calculating, based on the current noise signal, a frequency spectrum of a frequency band, and obtaining multiple discrete frequency points; and determining, based on one or any combination of a first criterion, a second criterion and a third criterion, whether the current noise signal has the arc feature.

Specifically, the determining based on the first criterion includes: counting the number of the multiple discrete frequency points which respectively have an amplitude greater than a first threshold; determining whether the number of frequency points respectively having an amplitude greater than a first threshold is greater than a second threshold, and determining that the current noise signal has the arc feature in a case that the number of points is greater than the second threshold.

Specifically, the determining based on the second criterion includes: calculating an average amplitude of the multiple discrete frequency points; counting the number of the multiple discrete frequency points meeting a preset requirement, where the preset requirement refers to that an absolute value of a difference between an amplitude of a frequency point and the average amplitude is less than a third threshold; determining whether the number of the discrete frequency points meeting the preset requirement is greater than a fourth threshold, and determining that the current noise signal has the arc feature in a case that the number of the discrete frequency points meeting the preset requirement is greater than the fourth threshold.

Specifically, the determining based on the third criterion includes: calculating an average amplitude of the multiple discrete frequency points; determining whether the average amplitude is greater than a fifth threshold, and determining that the current noise signal has the arc feature in a case that the average amplitude is greater than the fifth threshold.

Optionally, after the second criterion is implemented, the method further includes:

filtering out a frequency point not meeting the preset requirement from the multiple discrete frequency points, and updating the average amplitude of the multiple discrete frequency points with an average amplitude of frequency points remaining after filtering out the frequency points.

Optionally, before sending a photovoltaic system direct-current arc fault signal, the method further includes:

updating a preset times of matching with an arc feature, where the times of matching with an arc feature are increased in a case that the current noise signal has the arc feature, and the times of matching with an arc feature are decreased in a case that the current noise signal does not have the arc feature;

controlling the times of matching with an arc feature to return to zero in a case that the times of matching with an arc feature are less than zero; and

proceeding to the step of sending a photovoltaic system direct-current arc fault signal in a case that the times of matching with an arc feature are increased to a sixth threshold.

A device for detecting a direct-current arc fault of a photovoltaic system is provided, which includes:

an operation parameters obtaining unit configured to obtain operation parameters of the photovoltaic system;

a current noise signal obtaining unit configured to obtain a current noise signal in a direct-current cable of the photovoltaic system;

a dynamic threshold determining unit, connected to the operation parameters obtaining unit and configured to adjust, based on the operation parameters, a threshold, where the threshold is used to determine whether the current noise signal has an arc feature; and

an arc feature processing unit, connected to the dynamic threshold determining unit and the current noise signal obtaining unit, respectively, and configured to determine, based on the threshold, whether the current noise signal has the arc feature, and send a photovoltaic system direct-current arc fault signal in a case that the current noise signal has the arc feature.

Specifically, the operation parameters obtaining unit includes:

an operation temperature signal obtaining unit configured to obtain an operation temperature signal of the photovoltaic system; and/or

a direct current signal obtaining unit configured to obtain a direct current signal in a direct-current cable of the photovoltaic system.

A system for detecting a direct-current arc fault of a photovoltaic system includes a processor, and the processor is configured to: obtain operation parameters of the photovoltaic system and a current noise signal in a direct-current cable of the photovoltaic system, respectively; adjust, based on the operation parameters, a threshold, where the threshold is used to determine whether the current noise signal has the arc feature; and send a photovoltaic system direct-current arc fault signal in a case that it is determined based on the threshold that the current noise signal has the arc feature.

A system for detecting a direct-current arc fault of a photovoltaic system is provided, which includes:

an operation parameters acquisition unit configured to sample operation parameters of a photovoltaic system;

an alternating current sensor configured to sample a current noise signal in a direct-current cable of the photovoltaic system; and

the processor described above connected to the operation parameters acquisition unit and the alternating current sensor, respectively.

Optionally, the system for detecting a direct-current arc fault of the photovoltaic system further includes a local display module and/or a remote communication module connected to the processor.

According to the technical solutions described above, in order to adapt the method for detecting a direct-current arc fault of a photovoltaic system to the varied operation environment of the photovoltaic system, in the present disclosure, the threshold used in the method for detecting a direct-current arc fault of a photovoltaic system is adjusted dynamically based on a change in the operation parameters in the photovoltaic system, hence a method, based on a dynamic threshold, for detecting a direct-current arc fault of a photovoltaic system is obtained, which improves precision of the direct-current arc fault detection and alleviates the problem in the conventional technology.

### BRIEF DESCRIPTION OF THE DRAWINGS

In order to more clearly illustrate the technical solutions in the embodiments of the present disclosure or in the conventional technology, in the following, drawings for the description of the embodiments or the conventional technology will be introduced briefly. The drawings in the following description are merely embodiments of the present disclosure. For those skilled in the art, other drawings may also be obtained according to the provided drawings without any creative work

FIG. 1 is a flowchart of a method for detecting a direct-current arc fault of a photovoltaic system according to a first embodiment of the present disclosure;

FIG. 2 is a schematic diagram of secondary-side output attenuation of a current transformer having various loads and various primary-side direct currents according to a first embodiment of the present disclosure;

FIG. 3 is a frequency spectrum diagram of inherent noise, arc noise, and superimposition noise of the inherent noise and the arc noise, according to a first embodiment of the present disclosure;

FIG. 4 is a flowchart of a method for detecting a direct-current arc fault of a photovoltaic system by using a first criterion according to a first embodiment of the present disclosure;

FIG. 5 is a flowchart of a method for detecting a direct-current arc fault of a photovoltaic system by using a second criterion according to a first embodiment of the present disclosure;

FIG. 6 is a flowchart of a method for detecting a direct-current arc fault of a photovoltaic system by using a third criterion according to a first embodiment of the present disclosure;

FIG. 7a is a flowchart of a method for detecting a direct-current arc fault of a photovoltaic system by using multiple criterions according to a first embodiment of the present disclosure;

FIG. 7b is a flowchart of another method for detecting a direct-current arc fault of a photovoltaic system by using multiple criterions according to a first embodiment of the present disclosure;

FIG. 8 is a schematic structural diagram of a device for detecting a direct-current arc fault of a photovoltaic system according to a second embodiment of the present disclosure; and

FIG. 9 is a schematic structural diagram of a system for detecting a direct-current arc fault of a photovoltaic system according to a third embodiment of the present disclosure.

### DETAILED DESCRIPTION OF THE EMBODIMENTS

Hereinafter, the technical solutions in the embodiments of the present disclosure will be described clearly and completely in conjunction with the drawings in the embodiments of the present disclosure. Obviously, the described embodiments are merely a few embodiments of the present disclosure, but not all embodiments. All the other embodiments obtained by those skilled in the art based on the embodiments in the present disclosure without introducing creative work will fall within the scope of protection of the present disclosure.

### First Embodiment

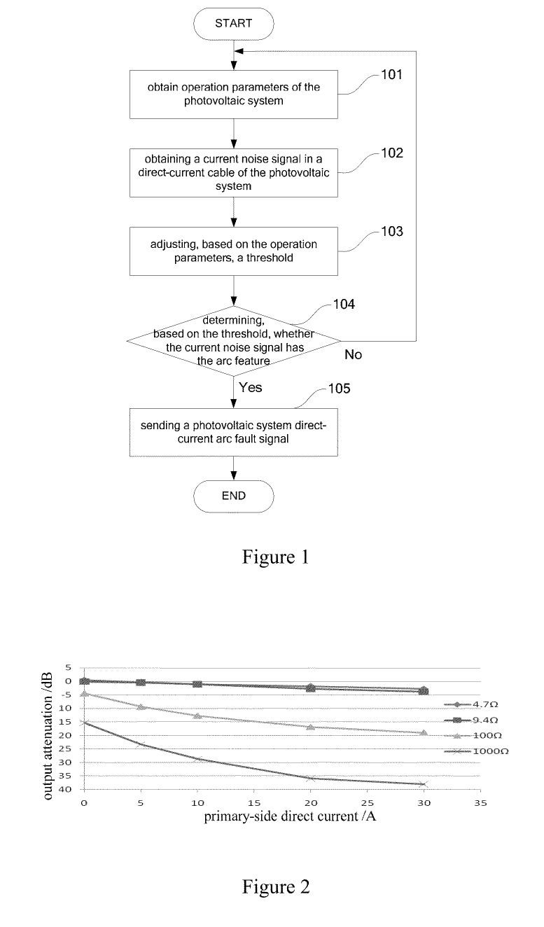

With reference to FIG. 1, a method for detecting a direct-current arc fault of a photovoltaic system is disclosed in the first embodiment of the present disclosure, to improve precision of the direct-current arc fault detection in the photovoltaic system, the method includes:

step 101, obtaining operation parameters of a photovoltaic system;

step 102, obtaining a current noise signal in a direct-current cable of the photovoltaic system; where an order for executing step 101 and step 102 is not limited, and this embodiment merely provides an exemplary order;

step 103, adjusting, based on the operation parameters, a threshold, where the threshold is used to determine whether the current noise signal has an arc feature;

step 104, determining based on the threshold whether the current noise signal has the arc feature; proceeding to step 105 in a case that the current noise signal has the arc feature, or returning to step 101 in a case that the current noise signal does not have the arc feature; and

step 105, sending a photovoltaic system direct-current arc fault signal.

In order to adapt the method for detecting a direct-current arc fault of a photovoltaic system to a varied operation environment of the photovoltaic system, in the embodiment, the threshold used in the method for detecting a direct-current arc fault of a photovoltaic system is adjusted dynamically based on a change in the operation parameters in the photovoltaic system, hence the method for detecting a direct-current arc fault of a photovoltaic system based on a dynamic threshold is obtained, which improves the precision of the direct-current arc fault detection and alleviates the problem in the conventional technology.

Steps 101 and 103 are a process for dynamically adjusting the threshold. Steps 102, 104 and 105 are a process for detecting, based on the current noise feature in the direct-current cable of the photovoltaic system, a direct-current arc fault. In order for those skilled in the art to understand and apply the method, the technical solutions in the first embodiment will be described based on details of the two processes.

1) As to Step 101 and Step 103

Operation parameters of the photovoltaic system preferably include parameters significantly affecting precision of the direct-current arc fault detection, such as an operation temperature signal of the photovoltaic system and/or a direct current signal in the direct-current cable of the photovoltaic system. Details are provided as follows.

i) As to the Direct Current Signal in the Direct-Current Cable of the Photovoltaic System

There is uncertainty of a position where the direct-current arc fault occurs at a direct-current side of the photovoltaic system. But since noise at the direct-current side of the photovoltaic system (the noise is essentially an alternating-current) will be increased by the direct-current arc fault, whether the direct-current arc fault occurs can be determined based on an amplitude of current noise sampled by a current transformer. However, the current transformer is apt to saturate with increasing of a primary-side direct current, and then for a fixed amplitude of the current noise in the primary-side direct current, an amplitude of current noise outputted from a secondary side of the current transformer attenuates with the increasing of the primary direct current, which may result in misjudgment for the direct-current arc fault. FIG. 2 is a schematic diagram of secondary-side output attenuation of a current transformer having various loads and various primary-side direct currents.

ii) As to the Operation Temperature Signal of the Photovoltaic System

When the photovoltaic system operates at various ambient temperatures, some parameters of conductors or semiconductors in the photovoltaic system will change due to temperature drift, which has a severe affect on noise components at a direct-current side of the photovoltaic system and on sampling sensitivity of the current transformer, and then reduces precision in the direct-current arc fault detection.

In order to adapt to the varied operation environment of the photovoltaic system, in the embodiment, the arc feature of the current noise signal is no longer determined based on a fixed threshold, and the threshold is adjusted dynamically based on a change in the operation parameters of the photovoltaic system, and then it is determined whether the current noise signal has the arc feature. Specifically, a process of determining based on a operation temperature signal of the photovoltaic system and/or a direct current signal in the direct-current cable of the photovoltaic system, a threshold for the method for detecting a direct-current arc fault of a photovoltaic system includes:

giving a particular alternating-current signal for the method for detecting a direct-current arc fault of a photovoltaic system based on the dynamic threshold, and measuring in advance a rated response R in the method in a case of a rated operation temperature T_{N} and a rated direct current I_{N}; and then measuring responses k(T, I)*R in the method at various operation temperatures T and various direct current I;

where the rated response R includes a rated threshold Thr_{N} for the method, the factor k(T, I) is an adjustment factor for the dynamic threshold Thr, dynamic thresholds at various temperatures T and various direct current I are Thr=k(T, I) *Thr_{N};

The factor k(T, I) is at least related to one of the operation temperature T and the direct current I; and the factor k(T, I) may be a continuous function. The dynamic threshold Thr can be calculated directly according to the function in a case of a given operation temperature and a given direct current. For example, assuming that the factor k(T, I)=(1.2−0.2*T/T0)*(1.5−0.5*I/I0), and T0=25° C., I0=30A and Thr_{N}=200 represent a rated operation temperature, a rated direct current and a rated threshold, respectively, then a dynamic threshold in a case of an actual operation temperature T=0° C. and an actual direct current I=10A is Thr=k(T, I)*Thr_{N}=k(0, 10) *200=1.6*200=320. Or, the factor k(T, I) may also be discrete values, and a factor k(T, I) at a given operation temperature and a given direct current can be calculated by a method such as interpolation calculation or curve fitting.

2) As to Step 102, Step 104 and Step 105

Current noise in a direct-current cable of the photovoltaic system includes inherent noise, and arc noise caused by the direct-current arc fault; where the arc noise includes a characteristic approximate to pink noise, and approximates to white noise in a high frequency band, so it can be considered that arc energy is approximately evenly distributed at high frequencies. Energy of the inherent noise is mainly concentrated in a pulse width modulation chopping frequency of a switch device and in multiple frequency bands of the chopping frequency. The inherent noise is distributed non-evenly, and is shown as prominent peaks in a frequency spectrum.

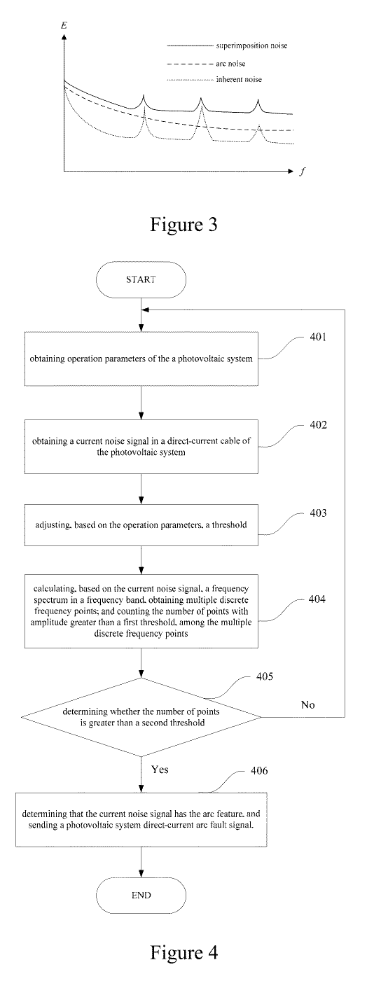

According to frequency spectra of the inherent noise, the arc noise, and superimposition noise of the inherent noise and the arc noise, as shown in FIG. 3, in a case that both the inherent noise and the arc exist, peaks in most of the inherent noise are not obvious in the frequency spectrum due to superimposition with the arc noise, and frequency spectrum of directly detected current noise (i.e. the superimposition noise) in the direct-current cable is smoother. In addition, due to the superimposition of the inherent noise and the arc noise after the direct-current arc fault occurs, the current noise in the direct-current cable of the photovoltaic system is increased due to the direct-current arc fault.

Based on this, three criterions for determining whether the current noise signal has the arc feature are provided in the embodiment. Specifically, step 104 includes: first, calculating, based on the current noise signal, a frequency spectrum in a frequency band, and obtaining multiple discrete frequency points; and then, determining, based on any one or any combination of a first criterion, a second criterion and a third criterion, whether the current noise signal has the arc feature. In the following, Illustration is provided by examples 1 to 4.

### Example 1

The first criterion includes: counting the number of points with amplitude greater than a first threshold, among the multiple discrete frequency points; determining whether the number of points is greater than a second threshold, and determining that the current noise signal has the arc feature in a case that the number of points is greater than the second threshold. Correspondingly, with reference to FIG. 4, a method for detecting a direct-current arc fault of a photovoltaic system by using the first criterion includes:

Step 401: obtaining operation parameters of a photovoltaic system;

Step 402: obtaining a current noise signal in a direct-current cable of the photovoltaic system;

Step 403: adjusting, based on the operation parameters, a threshold, where the threshold is used to determine whether the current noise signal has an arc feature;

Step 404: calculating, based on the current noise signal, a frequency spectrum in a frequency band, obtaining multiple discrete frequency points; and counting the number of points with amplitude greater than a first threshold, among the multiple discrete frequency points;

Step 405: determining whether the number of points is greater than a second threshold, and proceeding to step 406 in a case that the number of points is greater than the second threshold, or proceeding to step 401 in a case that the number of points is not greater than the second threshold;

Step 406: determining that the current noise signal has the arc feature, and sending a photovoltaic system direct-current arc fault signal.

Since the current noise in the direct-current cable of the photovoltaic system will be increased due to the direct-current arc fault, frequency points of the current noise signal in the same frequency band are extracted in the example 1. It is determined that the current noise signal has the arc feature in a case that the number of frequency points of the frequency points with great amplitude is large enough, otherwise it is determined that the current noise signal does not have the arc feature. Specifically, whether the amplitude of the frequency point is great is determined by a result obtained by comparing the amplitude of the frequency point with the first threshold. And the number of the frequency points with great amplitude is determined by a result obtained by comparing the number of the frequency points having great amplitude with the second threshold. Since the first threshold and the second threshold are dynamic thresholds determined by step 403, they track an operation environment of the photovoltaic system in a real time manner. Hence precision in the direct-current arc fault detection of the photovoltaic system is improved.

### Example 2

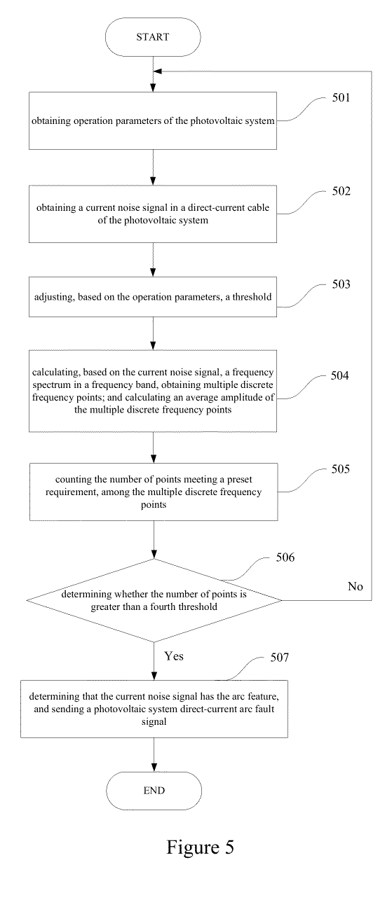

The second criterion includes: calculating an average amplitude of the multiple discrete frequency points; counting the number of points meeting a preset requirement, among the multiple discrete frequency points, where the preset requirement indicates that an absolute value of a difference between an amplitude of a frequency point and the average amplitude is less than a third threshold; determining whether the number of the points meeting the preset requirement is greater than a fourth threshold; and determining that the current noise signal has the arc feature in a case that the number of points meeting the preset requirement is greater than the fourth threshold. Correspondingly, with reference to FIG. 5, a method for detecting a direct-current arc fault of a photovoltaic system by using the second criterion includes:

Step 501: obtaining operation parameters of the photovoltaic system;

Step 502: obtaining a current noise signal in a direct-current cable of the photovoltaic system;

Step 503: adjusting, based on the operation parameters, a threshold, where the threshold is used to determine whether the current noise signal has an arc feature;

Step 504: calculating, based on the current noise signal, a frequency spectrum in a frequency band, obtaining multiple discrete frequency points; and calculating an average amplitude of the multiple discrete frequency points;

Step 505: counting the number of points meeting a preset requirement, among the multiple discrete frequency points, where the preset requirement indicates that an absolute value of a difference between an amplitude of a frequency point and the average amplitude is less than a third threshold;

Step 506: determining whether the number of points meeting the preset requirement is greater than a fourth threshold, and proceeding step 507 in a case that the number of points meeting the preset requirement is greater than the fourth threshold, or proceeding to step 501 in a case that the number of points meeting the preset requirement is not greater than the fourth threshold.

Step 507: determining that the current noise signal has the arc feature, and sending a photovoltaic system direct-current arc fault signal.

Since the spectrum of superimposition noise is smoother than that of the inherent noise, frequency points of the current noise signal in the same frequency band are extracted in example 2. It is determined that the current noise signal has the arc feature in a case that the number of frequency points of the frequency points having close amplitude is large enough, otherwise it is determined that the current noise signal does not have the arc feature. Specifically, whether the frequency points have close amplitude depends on whether amplitude of the frequency points fall within a preset width beside the average amplitude (the width equals to the third threshold). The number of frequency points having close amplitude is determined by a result obtained by comparing the number of the frequency points having close amplitude with the fourth threshold. Since the third threshold and the fourth threshold are dynamic thresholds determined by step 503, they track an operation environment of the photovoltaic system in a real time manner. Hence precision in the direct-current arc fault detection in the photovoltaic system is improved.

### Example 3

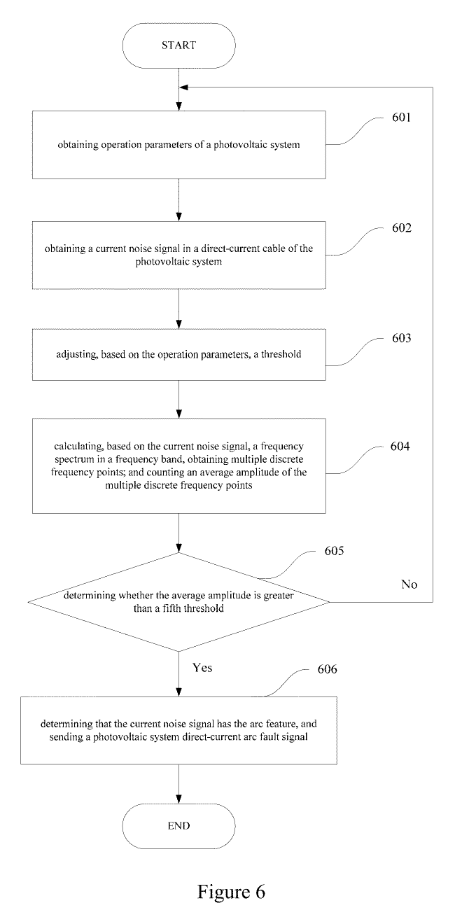

The third criterion includes: calculating an average amplitude of the multiple discrete frequency points; determining whether the average amplitude is greater than a fifth threshold, and determining that the current noise signal has the arc feature in a case that the average amplitude is greater than the fifth threshold. Correspondingly, with reference to FIG. 6, a method for detecting a direct-current arc fault of a photovoltaic system using the third criterion includes:

Step 601: obtaining operation parameters of a photovoltaic system;

Step 602: obtaining a current noise signal in a direct-current cable of the photovoltaic system;

Step 603: adjusting, based on the operation parameters, a threshold, where the threshold is used to determine whether the current noise signal has an arc feature;

Step 604: calculating, based on the current noise signal, a frequency spectrum in a frequency band, obtaining multiple discrete frequency points; and counting an average amplitude of the multiple discrete frequency points;

Step 605: determining whether the average amplitude is greater than a fifth threshold, and proceeding to step 606 in a case that the average amplitude is greater than the fifth threshold, or returning to step 601 in a case that the average amplitude is not greater than the fifth threshold.

Step 606: determining that the current noise signal has the arc feature, and sending a photovoltaic system direct-current arc fault signal.

Since the current noise in the direct-current cable of the photovoltaic system will be increased due to the direct-current arc fault, frequency points of the current noise signal at the same frequency band are extracted in the example 3, it is determined that the current noise signal has the arc feature in a case that the amplitudes of frequency points all increase correspondingly, or else it is determined that the current noise signal does not have the arc feature. Specifically, whether an amplitude of a frequency point increases depends on whether the average value of the amplitudes of the frequency points increases to be greater than the fifth threshold. Since the fifth threshold is a dynamic thresholds determined by step 603, which track an operation environment of the photovoltaic system in a real time manner, hence the precision of the direct-current arc fault detection in the photovoltaic system is raised.

### Example 4

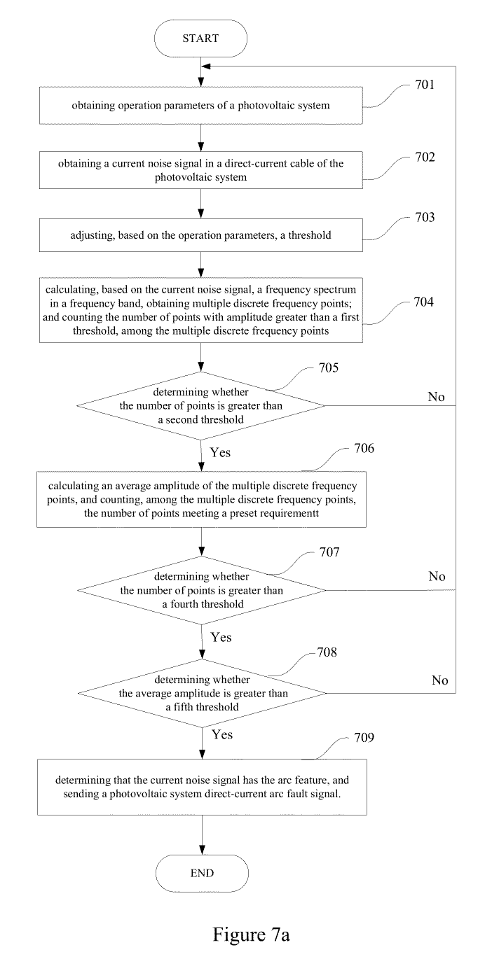

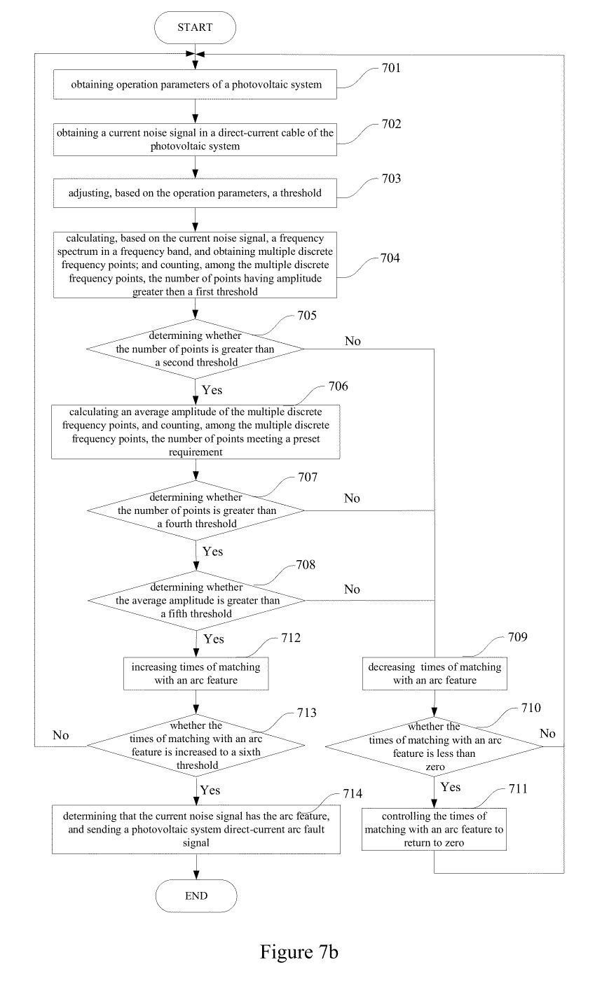

With reference to FIG. 7a, a method for detecting a direct-current arc fault of a photovoltaic system by using the first criterion, the second criterion and the third criterion described above includes:

Step 701: obtaining operation parameters of a photovoltaic system;

Step 702: obtaining a current noise signal in a direct-current cable of the photovoltaic system;

Step 703: adjusting, based on the operation parameters, a threshold, where the threshold is used to determine whether the current noise signal has an arc feature;

Step 704: calculating, based on the current noise signal, a frequency spectrum in a frequency band, obtaining multiple discrete frequency points; and counting the number of points with amplitude greater than a first threshold, among the multiple discrete frequency points;

Step 705: determining whether the number of points with amplitude greater than a first threshold is greater than a second threshold, and proceeding to step 706 in a case that the number of points is greater than the second threshold, or returning to step 701 in a case that the number of points is not greater than the second threshold;

Step 706: calculating an average amplitude of the multiple discrete frequency points, and counting, among the multiple discrete frequency points, the number of points meeting a preset requirement, where the preset requirement indicates that an absolute value of a difference between an amplitude of a frequency point and the average amplitude is less than a third threshold;

Step 707: determining whether the number of points is greater than a fourth threshold, and proceeding to step 708 in a case that the number of points is greater than the fourth threshold, or returning to step 701 in a case that the number of points is not greater than the fourth threshold;

Step 708: determining whether the average amplitude of the multiple discrete frequency points is greater than a fifth threshold, and proceeding to step 709 in a case that the average amplitude of the multiple discrete frequency points is greater than the fifth threshold, or returning to step 701 in a case that the average amplitude of the multiple discrete frequency points is not greater than the fifth threshold;

Step 709: determining that the current noise signal has the arc feature, and sending a photovoltaic system direct-current arc fault signal.

Examples 1 to 3 are combined in example 4. It will proceed to step 709 only in a case that all the three criterions (the first criterion in step 704 to 705, the second criterion in step 706 to 707, and the third criterion in step 708) are met. Hence a method for detecting a direct-current arc fault of a photovoltaic system by using multiple criterions (sequences for executing the three criterions are not limited thereto, merely a sequence for executing the three criterion is shown in example 4) is provided, which avoids limitation when only a single criterion is used, and enables high reliability and anti-interference.

Preferably, after step 707, the method further includes: filtering out frequency points not meeting the preset requirement, among the multiple discrete frequency points, and updating the average amplitude of the multiple discrete frequency points, with average amplitude of frequency points remaining after filtering out the frequency points (not shown in FIG. 7a). Accordingly, in step 708, the processing is based on the average value obtained after the interference frequency points are removed, and a result of the processing is more accurate.

Preferably, based on any one example described above, before sending the photovoltaic system direct-current arc fault signal, the method further includes: updating preset times of matching with an arc feature. Specifically, the times of matching with an arc feature are increased in a case that the current noise signal has the arc feature, or the times of matching with an arc feature are decreased in a case that the current noise signal does not have an arc feature; controlling the times of matching with an arc feature to return to zero in a case that the times of matching with an arc feature are less than zero; processing to the step of sending the photovoltaic system direct-current arc fault signal in a case that the times of matching with an arc feature are increased to a sixth threshold. Taking example 4 as an example, with reference to FIG. 7b, a preferable embodiment includes:

step 701: obtaining operation parameters of a photovoltaic system;

step 702: obtaining a current noise signal in a direct-current cable of the photovoltaic system;

step 703: adjusting, based on the operation parameters, a threshold, where the threshold is used to determine whether the current noise signal has an arc feature;

step 704: calculating, based on the current noise signal, a frequency spectrum in a frequency band, and obtaining multiple discrete frequency points; and counting, among the multiple discrete frequency points, the number of points having amplitude greater then a first threshold;

step 705: determining whether the number of points is greater than a second threshold, and proceeding to step 706 in a case that the number of points is greater than the second threshold, or proceeding to step 709 in a case that the number of points is not greater than the second threshold;

step 706: calculating an average amplitude of the multiple discrete frequency points, and counting, among the multiple discrete frequency points, the number of points meeting a preset requirement, where the preset requirement indicates that an absolute value of a difference between an amplitude of a frequency point and the average amplitude is less than a third threshold;

step 707: determining whether the number of points meeting the preset requirement is greater than a fourth threshold, and proceeding to step 708 in a case that the number of points is greater than the fourth threshold, or proceeding to step 709 in a case that the number of points is not greater than the fourth threshold;

step 708: determining whether the average amplitude of the multiple discrete frequency points is greater than a fifth threshold, and proceeding to step 712 in a case that the average amplitude is greater than the fifth threshold, or proceeding to step 709 in a case that the average amplitude is not greater than the fifth threshold;

step 709: decreasing preset times of matching with an arc feature, where an initial value of the times of matching with an arc feature may be set to be zero, but not limited thereto;

step 710: determining whether the times of matching with an arc feature are less than zero, proceeding to step 711 in a case that the times of matching with an arc feature are less than zero, or returning to 701 in a case that the times of matching with an arc feature are not less than zero;

step 711: controlling the times of matching with an arc feature to return to zero, and returning to step 701;

step 712: increasing times of matching with an arc feature;

step 713: determining whether the times of matching with an arc feature are increased to a sixth threshold, proceeding to step 714 in a case that the times of matching with an arc feature are increased to the sixth threshold, or returning to step 701 in a case that the times of matching with an arc feature are not increased to a sixth threshold;

step 714: determining that the current noise signal has the arc feature, and sending a photovoltaic system direct-current arc fault signal.

In a case that the times of matching with an arc feature are decreased, it means no arc feature exists for a long time, and detected arc features may be caused by interference noise, and returning for further determination is required; and in a case that the times of matching with an arc feature are increased to the sixth threshold, it means that the arc feature exists for a long time, and a direct-current arc fault occurs. Hence, precision in direct-current arc detection of the photovoltaic system is further improved.

It should be noted that an increment of the times of matching with an arc feature may be set with respect to strength of the arc feature. For example, the times of matching with an arc feature will be increased by 2 in a case that the arc feature is extremely prominent, and the times of matching with an arc feature will be increased by 1 in a case that the arc feature is ordinarily prominent, to control a speed of determining the arc feature.

According to the description, in this embodiment, in order to adapt the method for direct-current arc fault detection method in the photovoltaic system to varied operation environment of the photovoltaic system, the threshold used in the method for detecting a direct-current arc fault of a photovoltaic system is adjusted dynamically based on a change in the operation parameters in the photovoltaic system. Hence a method for detecting a direct-current arc fault of a photovoltaic system based on the threshold is obtained, which improves precision in the direct-current arc fault detection and alleviates the problem in the conventional technology.

### Second Embodiment

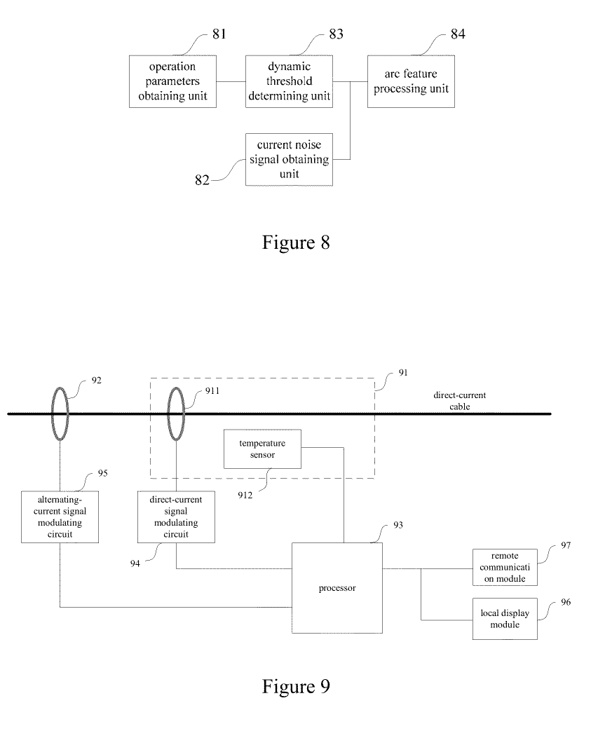

With reference to FIG. 8, a device for detecting a direct-current arc fault of a photovoltaic system is disclosed in the second embodiment of the present disclosure, to improve precision of direct-current arc detection in the photovoltaic system, the device includes:

an operation parameters obtaining unit 81 configured to obtain operation parameters of the photovoltaic system;

a current noise signal obtaining unit 82 configured to obtain a current noise signal in a direct-current cable of the photovoltaic system;

a dynamic threshold determining unit 83, connected to the operation parameters obtaining unit 81 and configured to adjust a threshold based on the operation parameters, where the threshold is used to determine whether the current noise signal has an arc feature;

an arc feature processing unit 84, connected to the dynamic threshold determining unit 83 and the current noise signal obtaining unit 82 and configured to determine based on the threshold whether the current noise signal has the arc feature, and send a photovoltaic system direct-current arc fault signal in a case that the current noise signal has the arc feature.

Specifically, the operation parameters obtaining unit 81 includes an operation temperature signal obtaining unit and/or a direct current signal obtaining unit (not shown in FIG. 8); the operation temperature signal obtaining unit is configured to obtain an operation temperature signal of the photovoltaic system, and the direct current signal obtaining unit is configured to obtain a direct current signal in a direct-current cable of the photovoltaic system.

Specifically, the arc feature processing unit 84 is configured to: calculate, based on the current noise signal, a frequency a spectrum in a frequency band, obtain multiple discrete frequency points, determine, based on one or any combination of a first criterion, a second criterion and a third criterion, whether the current noise signal has the arc feature, and send the photovoltaic system direct-current arc fault signal in a case that the current noise signal has the arc feature. Specifically, the first criterion includes: counting, among the multiple discrete frequency points, the number of points having amplitude greater than a first threshold; determining whether the number of points having amplitude greater than the first threshold is greater than a second threshold, and determining that the current noise signal has the arc feature in a case that the number of points is greater than the second threshold. The second criterion includes: calculating an average amplitude of the multiple discrete frequency points; counting, among the multiple discrete frequency points, the number of points meeting a preset requirement, where the preset requirement indicates that an absolute value of a difference between an amplitude of a frequency point and the average amplitude is less than a third threshold; determining whether the number of the points meeting the preset requirement is greater than a fourth threshold, and determining that the current noise signal has the arc feature in a case that the number of points is greater than the fourth threshold. The third criterion includes: calculating average amplitude of the multiple discrete frequency points; determining whether the average amplitude is greater than a fifth threshold, and determining that the current noise signal has the arc feature in a case that the average amplitude is greater than the fifth threshold.

Preferably, the arc feature processing unit 84 is further configured to, after implementing the second criterion, filter out, from the multiple discrete frequency points, frequency points not meeting the preset requirement, and update the average amplitude of the multiple discrete frequency points, with average amplitude of frequency points remaining after filtering out the frequency point.

Preferably, the arc feature processing unit 84 is further configured to, before sending the photovoltaic system direct-current arc fault signal, update a preset times of matching with an arc feature (the preset times of matching with an arc feature are increased in a case that the current noise signal has the arc feature, and the preset times of matching with an arc feature are decreased in a case that the current noise signal does not have the arc feature); control the times of matching with an arc feature to return to zero in a case that the times of matching with an arc feature are less than zero; proceeding to the step of sending the photovoltaic system direct-current arc fault signal in a case that the times of matching with an arc feature are increased to a sixth threshold.

### Third Embodiment

With reference to FIG. 9, a system for detecting a direct-current arc fault of a photovoltaic system including a processor is provided in the third embodiment, to improve precision of direct-current arc fault detection in the photovoltaic system. The processor is configured to: obtain operation parameters of a photovoltaic system and a current noise signal in a direct-current cable of the photovoltaic system, respectively; adjust, based on the operation parameters, a threshold, where the threshold is used to determine whether the current noise signal has an arc feature; and send a photovoltaic system direct-current arc fault signal in a case that it is determined based on the threshold that the current noise signal has the arc feature.

Specifically, the operation parameters include an operation temperature signal of the photovoltaic system and/or a direct current signal in the direct-current cable of the photovoltaic system.

Specifically, the processor is configured to calculate, based on the current noise signal, a frequency spectrum in a frequency band, obtain multiple discrete frequency points, and determine, based on any one or any combination of the three criterions described in the second embodiment, whether the current noise signal has the arc feature.

In addition, a system for detecting direct-current arc fault of a photovoltaic system is further disclosed in the third embodiment. With reference to FIG. 9, the system includes an operation parameters acquisition unit 91, an alternating current sensor 92, and a processor 93 connected to the operation parameters acquisition unit 91 and the alternating current sensor 92.

The processor 93 is any one processor described above.

The alternating current sensor 92 is configured to sample an alternating current signal (i.e. the current noise signal) in the direct-current cable of the photovoltaic system.

The operation parameters acquisition unit 91 is configured to sample operation parameters of the photovoltaic system, which includes a direct current sensor 911 and a temperature sensor 912; the direct current sensor 911 is configured to sample a direct current signal in the direct-current cable of the photovoltaic system; and the temperature sensor 912 is configured to detect an operation temperature of the photovoltaic system, and output a temperature signal.

Optionally, also with reference to FIG. 9, the system for detecting a direct-current arc fault of a photovoltaic system further includes: a direct-current signal modulating circuit 94 connected between the direct current sensor 911 and the processor 93, and an alternating-current signal modulating circuit 95 connected between the alternating current sensor 92 and the processor 93. Specifically, the direct-current signal modulating circuit 94 is configured to amplify and filter the direct current signal, and the alternating-current modulating circuit 95 is configured to amplify and filter the alternating current signal.

Optionally, also with reference to FIG. 9, the system for detecting a direct-current arc fault of a photovoltaic system further includes: a local display module 96 and/or a remote communication module 97, connected to the processor 93.

In summary, in order to adapt the method for detecting a direct-current arc fault of a photovoltaic system to varied operation environment of the photovoltaic system, in the embodiment, the threshold in the method for detecting a direct-current arc fault of a photovoltaic system is adjusted dynamically based on a change in the operation parameters of the photovoltaic system. Hence a method for detecting a direct-current arc fault of a photovoltaic system based on the dynamic threshold is obtained, which improves precision of the direct-current arc fault detection and alleviates the problem in the conventional technology.

The embodiments of the present disclosure are described herein in a progressive manner. Each of the embodiments emphasizes the difference from other embodiments. Hence, for the same or similar parts between the embodiments, one can refer to the other embodiments. Since the device for detecting a direct-current arc fault of a photovoltaic system based on the dynamic threshold, the processor and the system for detecting a direct-current arc fault of a photovoltaic system disclosed in the embodiments correspond to the method for detecting a direct-current arc fault of a photovoltaic system based on the dynamic threshold disclosed in the embodiments, the description of the device, the processor and the system are brief, and related parts can refer to the description of the method parts.

The above description of the embodiments herein enables those skilled in the art to implement or use the disclosure. Various modifications to these embodiments will be obvious to those skilled in the art, and the general principle defined herein can be implemented in other embodiments without deviation from the spirit or scope of the present disclosure. Therefore, the present disclosure will not be limited to these embodiments described herein, but in accordance with the widest scope consistent with the principle and novel features disclosed herein.

What is claimed is:

1. A method for detecting a direct-current arc fault of a photovoltaic system, comprising:
obtaining operation parameters of a photovoltaic system and a current noise signal in a direct-current cable of the photovoltaic system, respectively;
adjusting, based on the operation parameters, a threshold, wherein the threshold is used to determine whether the current noise signal has an arc feature; and
sending a photovoltaic system direct-current arc fault signal in a case that it is determined, based on the threshold, that the current noise signal has the arc feature.

2. The method according to claim 1, wherein the operation parameters comprise an operation temperature signal of the photovoltaic system and/or a direct current signal in the direct-current cable of the photovoltaic system.

3. The method according to claim 1, wherein determining, based on the threshold, whether the current noise signal has an arc feature, comprises:
calculating, based on the current noise signal, a frequency spectrum of a frequency band, and obtaining a plurality of discrete frequency points; and
determining, based on one or any combination of a first criterion, a second criterion and a third criterion, whether the current noise signal has an arc feature;
wherein the determining based on the first criterion comprises: counting a number of frequency points of the plurality of discrete frequency points which respectively have an amplitude greater than a first threshold; determining whether the number of the frequency points respectively having an amplitude greater than the first threshold is greater than a second threshold, and determining that the current noise signal has the arc feature in a case that the number of the frequency points respectively having an amplitude greater than the first threshold is greater than the second threshold;
wherein the determining based on the second criterion comprises: calculating an average amplitude of the plurality of discrete frequency points; counting a number of the discrete frequency points meeting a preset requirement, and wherein the preset requirement refers to that an absolute value of a difference between an amplitude of a frequency point and the average amplitude is smaller than a third threshold; determining whether the number of the discrete frequency points meeting the preset requirement is greater than a fourth threshold, and determining that the current noise signal has the arc feature in a case that the number of the discrete frequency points meeting the preset requirement is greater than the fourth threshold;
wherein the determining based on the third criterion comprises: calculating an average amplitude of the plurality of discrete frequency points; determining whether the average amplitude is greater than a fifth threshold, and determining that the current noise signal has the arc feature in a case that the average amplitude is greater than the fifth threshold.

4. The method according to claim 2, wherein the determining, based on the threshold, whether the current noise signal has an arc feature, comprises:
calculating, based on the current noise signal, a frequency spectrum of a frequency band, and obtaining a plurality of discrete frequency points; and
determining, based on one or any combination of a first criterion, a second criterion and a third criterion, whether the current noise signal has an arc feature;
wherein the determining based on the first criterion comprises: counting a number of frequency points of the plurality of discrete frequency points which respectively have an amplitude greater than a first threshold; determining whether the number of the frequency points respectively having an amplitude greater than a first threshold is greater than a second threshold, and determining that the current noise signal has the arc feature in a case that the number of the frequency points respectively having an amplitude greater than the first threshold is greater than the second threshold;
wherein the determining based on the second criterion comprises: calculating an average amplitude of the plurality of discrete frequency points; counting a number of the discrete frequency points meeting a preset requirement, and wherein the preset requirement refers to that an absolute value of a difference between an amplitude of a frequency point and the average amplitude is smaller than a third threshold; determining whether the number of the discrete frequency points meeting the preset requirement is greater than a fourth threshold, and determining that the current noise signal has the arc feature in a case that the number of the discrete frequency points meeting the preset requirement is greater than the fourth threshold;
wherein the determining based on the third criterion comprises: calculating an average amplitude of the plurality of discrete frequency points; determining whether the average amplitude is greater than a fifth threshold, and determining that the current noise signal has the arc feature in a case that the average amplitude is greater than the fifth threshold.

5. The method according to claim 3, wherein after the second criterion is implemented, the method further comprises:
filtering out a frequency point not meeting the preset requirement from the plurality of discrete frequency points, and updating the average amplitude of the plurality of discrete frequency points with an average amplitude of frequency points remaining after filtering out the frequency point.

6. The method according to claim 4, wherein after the second criterion is implemented, the method further comprises:
filtering out a frequency point not meeting the preset requirement from the plurality of discrete frequency points, and updating the average amplitude of the plurality of discrete frequency points with an average amplitude of frequency points remaining after filtering out the frequency point.

7. The method according to claim 1, wherein before the sending a photovoltaic system direct-current arc fault signal, the method further comprises:
updating preset times of matching with an arc feature, wherein the times of matching with an arc feature are increased in a case that the current noise signal has the arc feature, and the times of matching with an arc feature are decreased in a case that the current noise signal does not have the arc feature;
controlling the times of matching with an arc feature to return to zero in a case that the times of matching with an arc feature are less than zero; and
proceeding to the step of sending the photovoltaic system direct-current arc fault signal in a case that the times of matching with an arc feature are increased to a sixth threshold.

8. A device for detecting a direct-current arc fault of a photovoltaic system, comprising:
an operation parameters obtaining unit configured to obtain operation parameters of the photovoltaic system;
a current noise signal obtaining unit configured to obtain a current noise signal in a direct-current cable of the photovoltaic system;
a dynamic threshold determining unit, connected to the operation parameters obtaining unit and configured to adjust, based on the operation parameters, a threshold, wherein the threshold is used to determine whether the current noise signal has an arc feature; and
an arc feature processing unit, connected to the dynamic threshold determining unit and the current noise signal obtaining unit, respectively, and configured to determine, based on the threshold, whether the current noise signal has the arc feature, and send a photovoltaic system direct-current arc fault signal in a case that the current noise signal has the arc feature.

9. The device according to claim 8, wherein the operation parameters obtaining unit comprises:
an operation temperature signal obtaining unit configured to obtain an operation temperature signal of the photovoltaic system; and/or a direct current signal obtaining unit configured to obtain a direct current signal in a direct-current cable of the photovoltaic system.

10. A system for detecting a direct-current arc fault of a photovoltaic system, comprising a processor, wherein the processor is configured to: obtain operation parameters of the photovoltaic system, and a current noise signal in a direct-current cable of the photovoltaic system, respectively; adjust, based on the operation parameters, a threshold, wherein the threshold is used to determine whether the current noise signal has an arc feature; and send a photovoltaic system direct-current arc fault signal in a case that it is determined based on the threshold that the current noise signal has the arc feature.

11. The system according to claim 10, further comprising:
an operation parameters acquisition unit configured to sample operation parameters of the photovoltaic system;
an alternating current sensor configured to sample a current noise signal in the direct-current cable of the photovoltaic system;
wherein the processor is connected to the operation parameters acquisition unit and the alternating current sensor, respectively.

12. The system according to claim 11, further comprising:
a local display module and/or a remote communication module connected to the processor.
